(19) United States
(12) Patent Application Publication
(10) Pub. No.: US 2023/0189662 A1
(43) Pub. Date: Jun. 15, 2023

(54) MAGNETIC MEMORY DEVICE

(71) Applicant: KIOXIA CORPORATION, Tokyo (JP)

(72) Inventor: Masatoshi YOSHIKAWA, Setagaya Tokyo (JP)

(21) Appl. No.: 17/901,773

(22) Filed: Sep. 1, 2022

(30) Foreign Application Priority Data
Dec. 13, 2021 (JP) 2021-201548

(51) Int. Cl. H01L 43/04; H01L 27/22; H01L 43/06; H01L 43/10

(52) U.S. Cl. CPC H01L 43/04; H01L 27/224; H01L 27/228; H01L 43/06; H01L 43/10

(57) ABSTRACT

A magnetic memory device includes first, second, and third conductor layers, and a memory cell that is coupled to the first, second, and third conductor layers. The memory cell includes a fourth conductor layer and a magnetoresistance effect element. The fourth conductor layer includes first, second, and third portions coupled to the first, second, and third conductor layers, respectively. The third portion is between the first and second portions. The magnetoresistance effect element is coupled between a third conductor and the fourth conductor layer. The fourth conductor layer includes a magnetic layer and a non-magnetic layer that is between the magnetic layer and the magnetoresistance effect element. The magnetic layer has a first saturation magnetization during a standby state or a read state of the memory cell, and has a second saturation magnetization larger than the first saturation magnetization during a write state of the memory cell.

### CROSS-REFERENCE TO RELATED APPLICATION(S)

This application is based upon and claims the benefit of priority from Japanese Patent Application No. 2021-201548, filed Dec. 13, 2021, the entire contents of which are incorporated herein by reference.

### FIELD

Embodiments described herein relate generally to a magnetic memory device.

### BACKGROUND

Magnetic memory devices using a magnetoresistance effect element as a storage element are known. Various methods have been proposed as a method for writing data into the magnetoresistance effect element.

### DESCRIPTION OF THE DRAWINGS

FIG. 1 is a block view illustrating an example of a configuration of a magnetic memory device according to a first embodiment.

FIG. 2 is a circuit view illustrating an example of a circuit configuration of a memory cell array according to the first embodiment.

FIG. 3 is a plan view illustrating an example of a planar layout of the memory cell array according to the first embodiment.

FIG. 4 is a cross-sectional view taken along the line IV-IV of FIG. 3, illustrating an example of a cross-sectional structure of the memory cell array according to the first embodiment.

FIG. 5 is a cross-sectional view of a region V of FIG. 4, illustrating an example of a cross-sectional structure of a magnetoresistance effect element and a peripheral wiring according to the first embodiment.

FIG. 6 is a cross-sectional view of a region V of FIG. 4, illustrating an example of a cross-sectional structure of the magnetoresistance effect element and the peripheral wiring according to the first embodiment.

FIG. 7 is a view illustrating an example of a relationship between a temperature of a magnetic layer and saturation magnetization according to the first embodiment.

FIG. 8 is a view illustrating an example of a relationship between various operations in the magnetic memory device and characteristics of the magnetic layer according to the first embodiment.

FIG. 9 is a circuit view illustrating an example of a write operation in the magnetic memory device according to the first embodiment.

FIG. 10 is a cross-sectional view illustrating an example of the write operation in the magnetic memory device according to the first embodiment.

FIG. 11 is a cross-sectional view illustrating an example of the write operation in the magnetic memory device according to the first embodiment.

FIG. 12 is a cross-sectional view illustrating an example of a cross-sectional structure of a magnetoresistance effect element and a peripheral wiring according to a second embodiment.

FIG. 13 is a cross-sectional view illustrating an example of a cross-sectional structure of the magnetoresistance effect element and the peripheral wiring according to a second embodiment.

FIG. 14 is a view illustrating an example of a relationship between composition of a magnetic layer and saturation magnetization according to the second embodiment.

FIG. 15 is a view illustrating an example of a relationship between the composition and coercivity of the magnetic layer according to the second embodiment.

FIG. 16 is a view illustrating an example of a relationship between various operations in a magnetic memory device and characteristics of the magnetic layer according to the second embodiment.

FIG. 17 is a cross-sectional view illustrating an example of a write operation in the magnetic memory device according to the second embodiment.

FIG. 18 is a cross-sectional view illustrating an example of the write operation in the magnetic memory device according to the second embodiment.

FIG. 19 is a circuit view illustrating an example of a circuit configuration of a memory cell array according to a first modification example.

FIG. 20 is a circuit view illustrating an example of a circuit configuration of a memory cell array according to a second modification example.

FIG. 21 is a circuit view illustrating an example of a circuit configuration of a memory cell array according to a third modification example.

### DETAILED DESCRIPTION

Embodiments provide a magnetic memory device that improves memory cell retention characteristics.

In general, according to one embodiment, a magnetic memory device includes a first conductor layer, a second conductor layer, a third conductor layer, and a three-terminal type memory cell that is coupled to the first conductor layer, the second conductor layer, and the third conductor layer. The memory cell includes a fourth conductor layer that includes a first portion that is coupled to the first conductor layer, a second portion that is coupled to the second conductor layer, and a third portion that is coupled to the third conductor layer and located between the first portion and the second portion, and a magnetoresistance effect element that is coupled between the third conductor layer and the fourth conductor layer. The fourth conductor layer includes a magnetic layer and a first non-magnetic layer that is provided between the magnetic layer and the magnetoresistance effect element. The magnetic layer has a first saturation magnetization during a standby state or a read state of the memory cell, and has a second saturation magnetization larger than the first saturation magnetization during a write state of the memory cell.

Hereinafter, some embodiments will be described with reference to drawings. In the following description, components having the same function and configuration are designated by a common reference code. Further, when distinguishing a plurality of components having a common reference code, a suffix is added to the common reference code to distinguish the components. When it is not necessary to distinguish a plurality of components, only a common reference code is added to the plurality of components, and no subscript is added. Suffixes are not limited to subscripts and superscripts, and include, for example, lowercase alphabets, symbols, and indexes that mean sequences that are added to the end of the reference code.

In the present specification, a magnetic memory device is, for example, a magnetoresistive random access memory (MRAM). The magnetic memory device includes a magnetoresistance effect element as a storage element. The magnetoresistance effect element is a variable resistance element having a magnetoresistance effect by magnetic tunnel junction (MTJ). The magnetoresistance effect element is also referred to as an MTJ element.

### 1. First Embodiment

A first embodiment will be described.

### 1.1 Configuration

First, the configuration of a magnetic memory device according to a first embodiment will be described.

### 1.1.1 Magnetic Memory Device

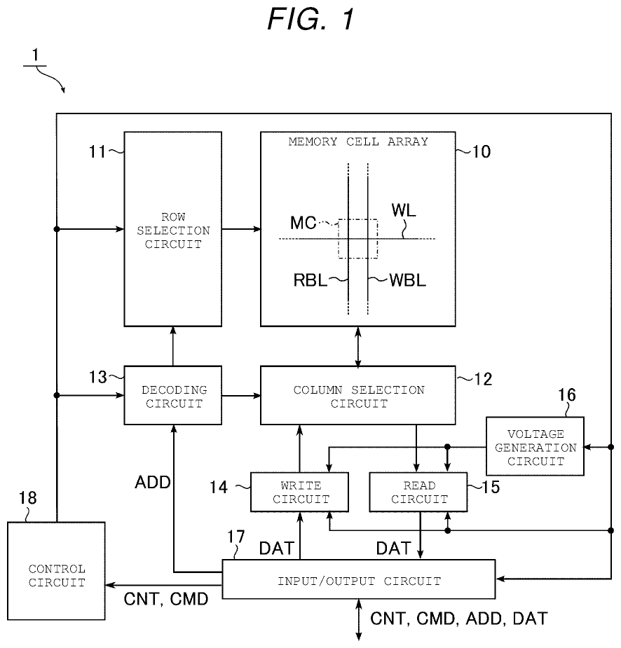

FIG. 1 is a block view illustrating an example of the configuration of the magnetic memory device according to the first embodiment. A magnetic memory device 1 includes a memory cell array 10, a row selection circuit 11, a column selection circuit 12, a decoding circuit 13, a write circuit 14, a read circuit 15, a voltage generation circuit 16, an input/output circuit 17, and a control circuit 18.

The memory cell array 10 is a data memory unit in the magnetic memory device 1. The memory cell array 10 includes a plurality of memory cells MC. Each of the plurality of memory cells MC is associated with a set of row and column. The memory cells MC in the same row are coupled to the same word line WL, and the memory cells MC in the same column are coupled to the same set of read bit line RBL and write bit line WBL.

The row selection circuit 11 is a circuit that selects the rows of the memory cell array 10. The row selection circuit 11 is coupled to the memory cell array 10 via a word line WL. The row selection circuit 11 is supplied with the decoding result (row address) of an address ADD from the decoding circuit 13. The row selection circuit 11 selects the word line WL corresponding to the row based on the decoding result of the address ADD. In the following, a word line WL that is selected is referred to as a selected word line WL. Further, a word line WL other than the selected word line WL is referred to as a non-selected word line WL.

The column selection circuit 12 is a circuit that selects the columns of the memory cell array 10. The column selection circuit 12 is coupled to the memory cell array 10 via the read bit line RBL and the write bit line WBL. The column selection circuit 12 is supplied with the decoding result (column address) of the address ADD from the decoding circuit 13. The column selection circuit 12 selects the read bit line RBL and the write bit line WBL corresponding to the column based on the decoding result of the address ADD. In the following, a read bit line RBL that is selected and a write bit line WBL that is selected will be referred to as a selected bit line RBL and a selected bit line WBL, respectively. Further, a read bit line RBL other than the selected bit line RBL and a write bit line WBL other than the selected bit line WBL are referred to as a non-selected bit line RBL and a non-selected bit line WBL, respectively.

The decoding circuit 13 is a decoder that decodes the address ADD from the input/output circuit 17. The decoding circuit 13 supplies the decoding result of the address ADD to the row selection circuit 11 and the column selection circuit 12. The address ADD includes a column address and a row address.

The write circuit 14 includes, for example, a write driver (not illustrated). The write circuit 14 writes data into the memory cell MC.

The read circuit 15 includes, for example, a sense amplifier (not illustrated). The read circuit 15 reads data from the memory cell MC.

The voltage generation circuit 16 uses a power supply voltage provided from the outside (not illustrated) of the magnetic memory device 1 to generate voltages for various operations of the memory cell array 10. For example, the voltage generation circuit 16 generates various voltages required for a write operation and outputs the voltages to the write circuit 14. Further, for example, the voltage generation circuit 16 generates various voltages required for a read operation and outputs the voltages to the read circuit 15.

The input/output circuit 17 controls communication with the outside of the magnetic memory device 1. The input/output circuit 17 transfers the address ADD from the outside of the magnetic memory device 1 to the decoding circuit 13. The input/output circuit 17 transfers a command CMD from the outside of the magnetic memory device 1 to the control circuit 18. The input/output circuit 17 communicates various control signals CNT between the outside of the magnetic memory device 1 and the control circuit 18. The input/output circuit 17 transfers data DAT from the outside of the magnetic memory device 1 to the write circuit 14, and outputs the data DAT transferred from the read circuit 15 to the outside of the magnetic memory device 1.

The control circuit 18 includes, for example, a processor such as a central processing unit (CPU) and a read only memory (ROM). The control circuit 18 controls the operations of the row selection circuit 11, the column selection circuit 12, the decoding circuit 13, the write circuit 14, the read circuit 15, the voltage generation circuit 16, and the input/output circuit 17 in the magnetic memory device 1 based on the control signal CNT and command CMD.

### 1.1.2 Memory Cell Array

Next, the configuration of the memory cell array of the magnetic memory device according to the first embodiment will be described.

### Circuit Configuration

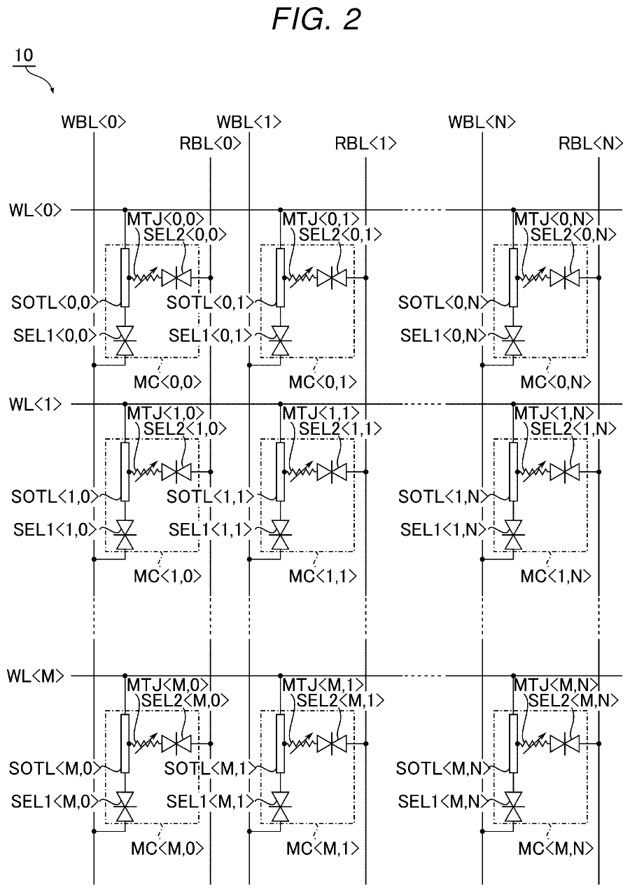

FIG. 2 is a circuit view illustrating an example of a circuit configuration of the memory cell array according to the first embodiment. In FIG. 2, each of the word line WL, the read bit line RBL, and the write bit line WBL is classified and illustrated by a suffix including an index (“< >”).

The memory cell array 10 includes a plurality of memory cells MC, a plurality of word lines WL, a plurality of read bit lines RBL, and a plurality of write bit lines WBL. In the example of FIG. 2, the plurality of memory cells MC includes (M+1)×(N+1) memory cells, MC<0, 0>, MC<0, 1>, . . . , MC<0, N>, MC<1, 0>, . . . , and MC<M, N> (where M and N are integers of 2 or more). In the example of FIG. 2, the case where M and N are integers of 2 or more is illustrated, but the present disclosure is not limited thereto. M and N may be 0 or 1. The plurality of word lines WL includes (M+1) word lines, WL<0>, WL<1>, and WL<M>. The plurality of read bit lines RBL includes (N+1) read bit lines, RBL<0>, RBL<1>, . . . , and RBL<N>. The plurality of write bit lines WBL includes (N+1) write bit lines, WBL<0>, WBL<1>, . . . , and WBL<N>.

The plurality of memory cells MC are arranged in a matrix form in the memory cell array 10. The memory cell MC is associated with a set that includes one of the plurality of word lines WL and a set of read bit line RBL and write bit line WBL of the plurality of read bit lines RBL and the plurality of write bit lines WBL. That is, the memory cell MC<i, j> (0≤i≤M, 0≤j≤N) is coupled to a word line WL<i>, a read bit line RBL<j>, and a write bit line WBL<j>.

The memory cell MC<i, j> is a three-terminal type memory cell including a first end coupled to the word line WL<i>, a second end coupled to the write bit line WBL<j>, and a third end coupled to the read bit line RBL<j>. The memory cell MC<i, j> includes switching elements SEL1<i, j> and SEL2<i, j>, a magnetoresistance effect element MTJ<i, j>, and a wiring SOTL<i, j>.

The wiring SOTL<i, j> includes a first portion, a second portion, and a third portion between the first portion and the second portion. The first portion of the wiring SOTL<i, j> is coupled to the word line WL<i>. The second portion of the wiring SOTL<i, j> is coupled to the write bit line WBL<j>. The third portion of the wiring SOTL<i, j> is coupled to the read bit line RBL<j>. The switching element SEL1<i, j> is coupled between the second portion of the wiring SOTL<i, j> and the write bit line WBL<j>. The magnetoresistance effect element MTJ<i, j> is coupled between the third portion of the wiring SOTL<i, j> and the read bit line RBL<j>. The switching element SEL2<i, j> is coupled between the magnetoresistance effect element MTJ<i, j> and the read bit line RBL<j>.

The switching elements SEL1 and SEL2 are two-terminal type switching elements. The two-terminal type switching element is different from a three-terminal type switching element such as a transistor. SEL1 and SEL2 have threshold voltages of Vth1 and Vth2, respectively. When the voltage applied to SEL1 and SEL2 is less than threshold voltages Vth1 and Vth2, respectively, the switching elements SEL1 and SEL2 are in a “high resistance” state or an “off” state. As a result, SEL1 and SEL2 are electrically non-conductive. When the voltages applied to SEL1 and SEL2 are equal to or higher than the threshold voltages Vth1 and Vth2, respectively, the state of the SEL1 and SEL2 change to a “low resistance” state or an “on” state. As a result, SEL1 and SEL2 are electrically conductive. More specifically, for example, when the voltage applied to the corresponding memory cell MC is lower than the threshold voltages Vth1 and Vth2, each of the switching elements SEL1 and SEL2 cuts off a current (enter an OFF state) as an insulator having a large resistance value. When the voltage applied to the corresponding memory cell MC exceeds the threshold voltages Vth1 and Vth2, each of the switching elements SEL1 and SEL2 passes a current (enter an ON state) as a conductor having a small resistance value. The switching elements SEL1 and SEL2 switch whether to pass or cut off the current depending on the magnitude of the voltage applied to the corresponding memory cell MC regardless of the polarity of the voltage applied between the two terminals (regardless of the direction of the flowing current).

The wiring SOTL is a current path in the memory cell MC. For example, when the switching element SEL1 is in an on state and the switching element SEL2 is in an off state, the wiring SOTL functions as a current path between the word line WL and the write bit line WBL. Further, for example, when the switching element SEL1 is in an off state and the switching element SEL2 is in an on state, a part of the wiring SOTL functions as a current path between the word line WL and the read bit line RBL.

The magnetoresistance effect element MTJ is a variable resistance element. The magnetoresistance effect element MTJ can switch the resistance value between a low resistance state and a high resistance state based on the current whose path is controlled by the switching elements SEL1 and SEL2. The magnetoresistance effect element MTJ functions as a storage element that stores data in a non-volatile manner by changing the resistance state thereof.

### Planar Layout

Next, the planar layout of the memory cell array according to the first embodiment will be described. In the following, a plane parallel to the surface of a substrate will be referred to as an XY plane. The direction in which the magnetic memory device 1 is provided with respect to the substrate surface is a Z direction or an upward direction. The directions that intersect each other in the XY plane are an X direction and a Y direction.

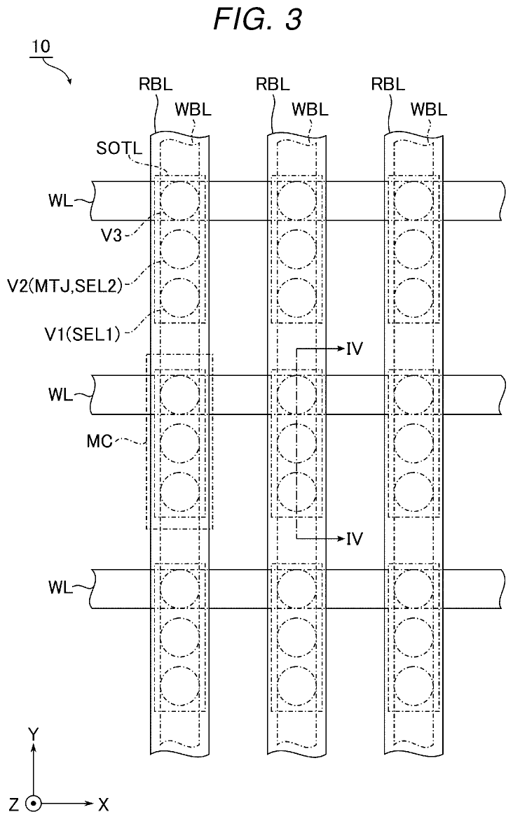

FIG. 3 is a plan view illustrating an example of the planar layout of the memory cell array according to the first embodiment. In FIG. 3, the structure such as an insulator layer is omitted.

The memory cell array 10 further includes a plurality of vertical structures V1, a plurality of vertical structures V2, and a plurality of vertical structures V3. Each of the plurality of vertical structures V1 includes the switching element SEL1. Each of the plurality of vertical structures V2 includes the magnetoresistance effect element MTJ and the switching element SEL2.

The plurality of write bit lines WBL are arranged in the X direction. Each of the plurality of write bit lines WBL extends in the Y direction.

Each of a plurality of word lines WL is provided above one of the plurality of write bit lines WBL. The plurality of word lines WL are arranged in the Y direction. Each of the plurality of word lines WL extends in the X direction.

Each of a plurality of wirings SOTL is provided above one of the plurality of word lines WL. In a plan view, each of the plurality of wirings SOTL has a rectangular shape that is longer in the Y direction than the X direction. Each of the plurality of wirings SOTL extends in the Y direction. In a plan view, each of the plurality of wirings SOTL is provided in a matrix form corresponding to a position overlapping with one word line WL and one write bit line WBL.

Each of a plurality of read bit lines RBL is provided above one of the plurality of wirings SOTL. The plurality of read bit lines RBL are arranged in the X direction. Each of the plurality of read bit lines RBL extends in the Y direction. In a plan view, each of the plurality of read bit lines RBL is provided at a position overlapping with the plurality of write bit lines WBL.

The plurality of vertical structures V1 extend in the Z direction. In a plan view, the plurality of vertical structures V1 have a circular shape. Each of the plurality of vertical structures V1 is between one corresponding write bit line WBL and one corresponding wiring SOTL. That is, each of the plurality of vertical structures V1 is coupled to the second portion of the corresponding wiring SOTL.

The plurality of vertical structures V2 extend in the Z direction. In a plan view, the plurality of vertical structures V2 have a circular shape. Each of the plurality of vertical structures V2 is between one corresponding read bit line RBL and one corresponding wiring SOTL. That is, each of the plurality of vertical structures V2 is coupled to the third portion of the corresponding wiring SOTL.

The plurality of vertical structures V3 extend in the Z direction. In a plan view, the plurality of vertical structures V3 have a circular shape. Each of the plurality of vertical structures V3 is between one corresponding word line WL and one corresponding wiring SOTL. That is, each of the plurality of vertical structures V3 is coupled to the first portion of the corresponding wiring SOTL.

Among the above configurations, a set of one wiring SOTL, one vertical structure V1 coupled to the one wiring SOTL, one vertical structure V2, and one vertical structure V3 functions as one memory cell MC.

### Cross-Sectional Structure

Next, the cross-sectional structure of the memory cell array according to the first embodiment will be described.

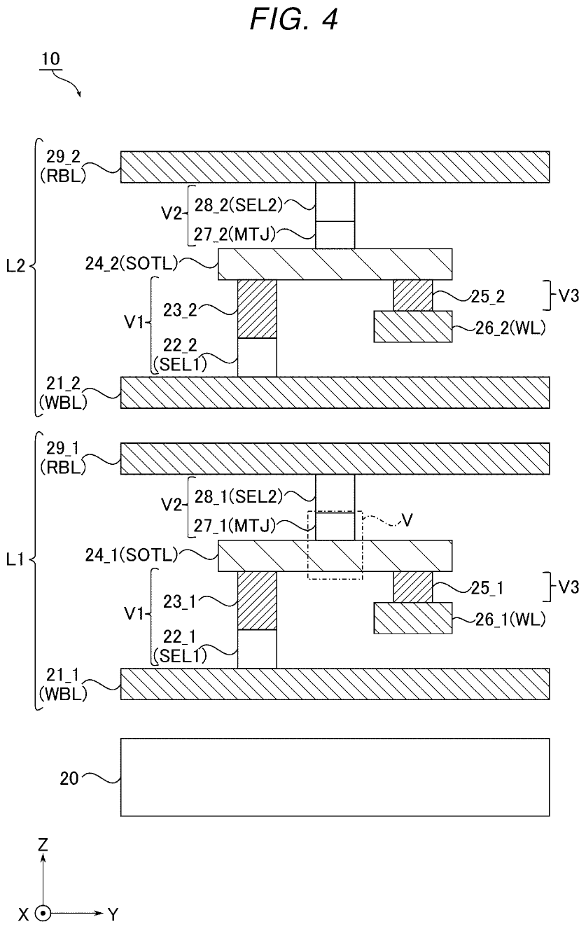

FIG. 4 is a cross-sectional view taken along the line IV-IV of FIG. 3, illustrating an example of the cross-sectional structure of the memory cell array according to the first embodiment. The memory cell array 10 includes a semiconductor substrate 20 and hierarchical structures L1 and L2. The hierarchical structure L1 includes conductor layers 21_1, 23_1, 24_1, 25_1, 26_1, and 29_1, as well as element layers 22_1, 27_1, and 28_1. The hierarchical structure L2 includes conductor layers 21_2, 23_2, 24_2, 25_2, 26_2, and 29_2, as well as element layers 22_2, 27_2, and 28_2. The configuration with a suffix “_x” indicates that the configuration belongs to a hierarchical structure Lx (x is an integer of 1 or more).

The hierarchical structures L1 and L2 are stacked in this order in the Z direction above the semiconductor substrate 20. Each of the hierarchical structures L1 and L2 corresponds to the planar layout illustrated in FIG. 3.

Peripheral circuits such as a row selection circuit 11 and a column selection circuit 12 may be provided between the semiconductor substrate 20 and the hierarchical structure L1. Alternatively, a circuit may not be formed between the semiconductor substrate 20 and the hierarchical structure L1. When a circuit is not formed between the semiconductor substrate 20 and the hierarchical structure L1, shallow trench isolation (STI) may be formed in a portion of the semiconductor substrate 20 located below the hierarchical structure L1.

The hierarchical structure L1 will be described.

The conductor layer 21_1 is provided above the semiconductor substrate 20. The conductor layer 21_1 is used as a write bit line WBL. The conductor layer 21_1 extends in the Y direction.

The element layer 22_1 is provided on the upper surface of the conductor layer 21_1. The element layer 22_1 is used as a switching element SEL1.

The conductor layer 23_1 is provided on the upper surface of the element layer 22_1. The conductor layer 23_1 is used as a contact. The element layer 22_1 and the conductor layer 23_1 constitute the vertical structure V1.

The conductor layer 24_1 is provided on the upper surface of the conductor layer 23_1. The conductor layer 24_1 is used as a wiring SOTL. The portion of the conductor layer 24_1 in contact with the conductor layer 23_1 corresponds to the second portion of the wiring SOTL. The conductor layer 24_1 extends in the Y direction.

The conductor layer 25_1 is provided on the lower surface of the portion of the conductor layer 24_1 that is different from the portion where the conductor layer 23_1 is provided. The portion of the conductor layer 24_1 in contact with the conductor layer 25_1 corresponds to the first portion of the wiring SOTL. The conductor layer 25_1 is used as a contact. The conductor layer 25_1 constitutes the vertical structure V3.

The conductor layer 26_1 is provided on the lower surface of the conductor layer 25_1. The conductor layer 26_1 is used as a word line WL. The conductor layer 26_1 extends in the X direction.

The element layer 27_1 is provided on the upper surface of the portion of the conductor layer 24_1 between the portion where the conductor layer 23_1 is provided and the portion where the conductor layer 25_1 is provided. The portion of the conductor layer 24_1 in contact with the element layer 27_1 corresponds to the third portion of the wiring SOTL. The element layer 27_1 is used as a magnetoresistance effect element MTJ.

The element layer 28_1 is provided on the upper surface of the element layer 27_1. The element layer 28_1 is used as a switching element SEL2. The element layers 27_1 and 28_1 constitute the vertical structure V2.

The conductor layer 29_1 is provided on the upper surface of the element layer 28_1. The conductor layer 29_1 is used as a read bit line RBL. The conductor layer 29_1 extends in the Y direction.

With the above configuration, the set of the conductor layers 24_1 in the hierarchical structure L1 and the vertical structures V1, V2, and V3 function as one memory cell MC having three terminals coupled to the conductor layers 21_1, 26_1, and 29_1, respectively.

The hierarchical structure L2 has the same configuration as the hierarchical structure L1. That is, the conductor layers 21_2, 23_2, 24_2, 25_2, 26_2, and 29_2, and the element layers 22_2, 27_2, and 28_2 have the same structures and functions as the conductor layers 21_1, 23_1, 24_1, 25_1, 26_1, and 29_1, and the element layers 22_1, 27_1, and 28_1, respectively. As a result, the set of conductor layers 24_2 in the hierarchical structure L2 and the vertical structures V1, V2, and V3 function as one memory cell MC having three terminals coupled to the conductor layers 21_2, 26_2, and 29_2, respectively.

### 1.1.3 Magnetoresistance Effect Element and Peripheral Wiring

Next, the configuration of the magnetoresistance effect element and the peripheral wiring of the magnetic memory device according to the first embodiment will be described.

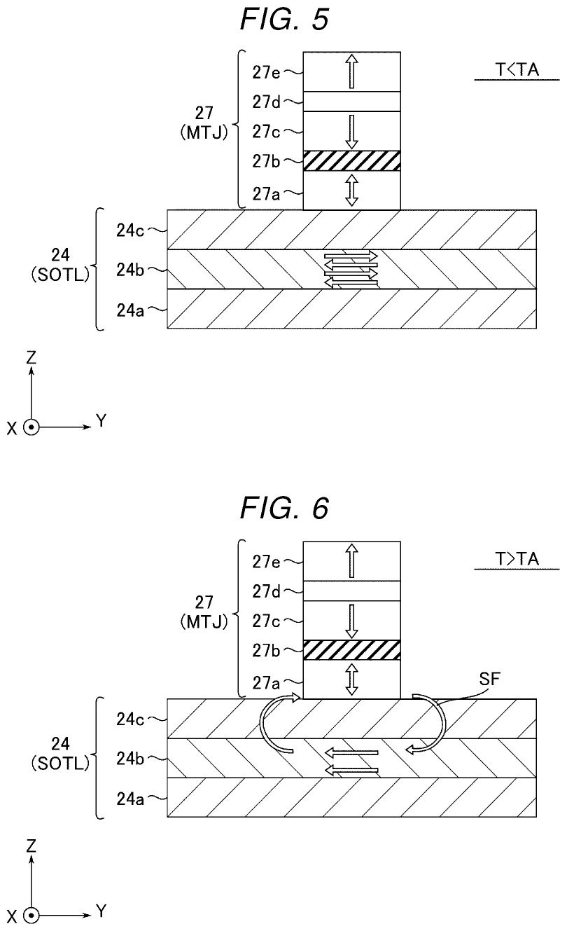

FIGS. 5 and 6 are cross-sectional views of the region V of FIG. 4, illustrating an example of the cross-sectional structure of the magnetoresistance effect element and the peripheral wiring according to the first embodiment. FIG. 5 corresponds to the case where the wiring SOTL is at a low temperature. FIG. 6 corresponds to the case where the wiring SOTL is at a high temperature.

The conductor layer 24 as the wiring SOTL includes a non-magnetic layer 24a, a magnetic layer 24b, and a non-magnetic layer 24c. The element layer 27 includes a ferromagnetic layer 27a, a non-magnetic layer 27b, a ferromagnetic layer 27c, a non-magnetic layer 27d, and a ferromagnetic layer 27e.

First, the details of the structure of the conductor layer 24 will be described.

The non-magnetic layer 24a is a non-magnetic conductive film. The non-magnetic layer 24a functions as a base layer of the magnetic layer 24b. From the viewpoint of improving film adhesion, the non-magnetic layer 24a contains tantalum (Ta), tungsten (W), titanium (Ti), titanium nitride (TiN), and the like. The film thickness of the non-magnetic layer 24a is preferably 0.5 nanometers or more and 5 nanometers or less. The lower limit of the film thickness of the non-magnetic layer 24a is determined from the viewpoint of the continuity of the film in the conductor layer 24. Further, from the viewpoint of preventing current shunting, the film thickness of the non-magnetic layer 24a is more preferably 3 nanometers or less.

The magnetic layer 24b is provided on the upper surface of the non-magnetic layer 24a. The magnetic layer 24b is a conductive film showing reversible magnetic phase change or magnetic phase transition between antiferro-magnetic phase and ferro-magnetic phase. The magnetic layer 24b has, for example, an alloy (FeRh alloy) containing iron (Fe) and rhodium (Rh). In the FeRh alloy, the composition ratio (at %) of iron and rhodium is around 50:50, and the magnetic phase transition (magnetic phase change) occurs. The composition ratio of iron in the FeRh alloy is preferably 50±10 at % (40 at % or more and 60 at % or less). The composition of the magnetic layer 24b can be analyzed in a thin film state by energy dispersive X-ray spectroscopy (EDX), secondary ion mass spectroscopy (SIMS), and fluorescent X-rays. From the viewpoint of preventing current shunting and generating Joule heat in the magnetic layer 24b, the magnetic layer 24b is preferably a thin film with a high resistance. The film thickness of the magnetic layer 24b is preferably 2 nanometers or more and 10 nanometers or less.

The magnetic phase change of the magnetic layer 24b occurs with a threshold temperature TA as a boundary. That is, the threshold temperature TA is the phase change temperature of the magnetic layer 24b. Specifically, as illustrated in FIG. 5, when a temperature T of the magnetic layer 24b is less than the threshold temperature TA (T<TA), the magnetic layer 24b exhibits the antiferro-magnetic property. On the other hand, as illustrated in FIG. 6, when the temperature T of the magnetic layer 24b exceeds the threshold temperature TA (T>TA), the magnetic layer 24b exhibits the ferromagnetic property.

When the magnetic layer 24b exhibits ferromagnetic property, the saturation magnetization (Ms) of the magnetic layer 24b is significantly larger than zero. The magnetic layer 24b generates a leakage magnetic field SF outside the magnetic layer 24b. The magnetization direction of the magnetic layer 24b is stabilized along the Y direction due to, for example, shape anisotropy. The magnetization direction of the magnetic layer 24b is reversed according to the direction of a current flowing in the magnetic layer 24b. That is, the magnetic layer 24b has an axial direction for easy magnetization in the extending direction (±Y direction) of the magnetic layer 24b. On the other hand, when the magnetic layer 24b exhibits antiferro-magnetic property, the magnetic moment of the magnetic layer 24b is internally canceled. As a result, the saturation magnetization Ms of the magnetic layer 24b becomes zero. Therefore, the magnetic layer 24b does not generate the leakage magnetic field SF outside the magnetic layer 24b.

The magnetic layer 24b may further contain iridium (Ir), palladium (Pd), ruthenium (Ru), osmium (Os), platinum (Pt), gold (Au), silver (Ag), or copper (Cu) as additives. When the FeRh alloy is used for the magnetic layer 24b, the additive is preferably added by substituting rhodium (Rh). By including the additive in the magnetic layer 24b, the threshold temperature TA can be adjusted to a desired value.

Further, the magnetic layer 24b may contain cobalt (Co) or nickel (Ni) as a further additive. The further additive is preferably added by substituting iron (Fe). In the case of containing the further additive, the magnetic layer 24b can adjust the saturation magnetization Ms in a ferromagnetic state. As a result, the strength of the leakage magnetic field SF from the magnetic layer 24b can be adjusted.

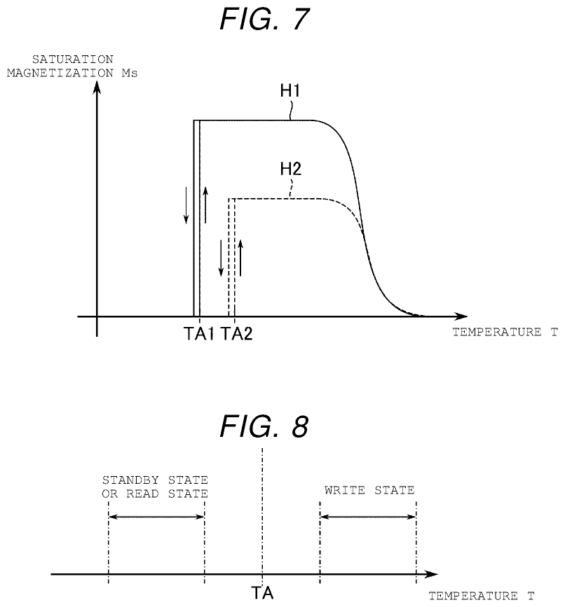

FIG. 7 is a view illustrating an example of a relationship between the temperature of the magnetic layer and saturation magnetization according to the first embodiment. In FIG. 7, hysteresis H1 and H2 of the saturation magnetization Ms to a change in the temperature T of the magnetic layer 24b are illustrated. The solid line hysteresis H1 corresponds to, for example, the case where the magnetic layer 24b does not contain an additive. The dashed hysteresis H2 corresponds to, for example, the case where the magnetic layer 24b contains an additive.

As illustrated in the hysteresis H1, when an additive is not contained, the magnetic layer 24b undergoes phase change at a threshold temperature TA1. On the other hand, as illustrated in the hysteresis H2, when an additive is contained, the magnetic layer 24b undergoes phase change at a threshold temperature TA2 higher than the threshold temperature TA1. By changing the composition ratio (at %) of the additive, the level of the threshold temperature TA2 and the saturation magnetization Ms after ferromagnetization can be adjusted. When the composition of the magnetic layer 24b containing an additive X is expressed as Feₐ(Rh_{(1-b)}X_{b})₍₁₀₀₋ₐ₎, a composition ratio b can be adjusted, for example, in a range of 0 at % or more and 0.1 at % or less.

The details of the structure of the conductor layer 24 will be described again with reference to FIGS. 5 and 6.

The non-magnetic layer 24c is provided on the upper surface of the magnetic layer 24b. The non-magnetic layer 24c is a conductive film made of a non-magnetic heavy metal. For example, the non-magnetic layer 24c contains at least one element selected from tantalum (Ta), tungsten (W), ruthenium (Ru), rhodium (Rh), palladium (Pd), silver (Ag), copper (Cu), osmium (Os), iridium (Ir), platinum (Pt), and gold (Au).

The non-magnetic layer 24c is a layer that generates a spin orbit torque (SOT) mainly caused by a spin hole effect due to a current flowing in the non-magnetic layer 24c. In order to obtain a large spin orbit torque, it is required to increase the current flowing through the non-magnetic layer 24c, that is, to increase the current density. Therefore, it is required to prevent the current shunting to the non-magnetic layer 24a and the magnetic layer 24b as other layers. The spin orbit torque acts on the ferromagnetic layer 27a. The film thickness of the non-magnetic layer 24c is preferably, for example, 0.3 nanometers or more and 10 nanometers or less. From the viewpoint of film continuity in the conductor layer 24, the film thickness of the non-magnetic layer 24c is preferably 1 nanometer or more.

Next, the details of the structure of the element layer 27 will be described.

The ferromagnetic layer 27a is provided on the upper surface of the non-magnetic layer 24c. The ferromagnetic layer 27a is a conductive film having ferro-magnetic property. The ferromagnetic layer 27a is used as a storage layer. The ferromagnetic layer 27a has an axial direction for easy magnetization in a direction perpendicular to the film surface (Z direction).

When the magnetic layer 24b exhibits antiferro-magnetic property, the leakage magnetic field SF is not applied to the ferromagnetic layer 27a. That is, when the magnetic layer 24b exhibits antiferro-magnetic property, no bias magnetic field is applied to the ferromagnetic layer 27a. On the other hand, when the magnetic layer 24b exhibits ferro-magnetic property, the leakage magnetic field SF is applied to the ferromagnetic layer 27a. That is, when the magnetic layer 24b exhibits ferro-magnetic property, a bias magnetic field is applied to the ferromagnetic layer 27a. The spin orbit torque generated in the non-magnetic layer 24c acts on the ferromagnetic layer 27a. When the leakage magnetic field SF of a predetermined magnitude is applied and the spin orbit torque of a predetermined magnitude is applied, the magnetization direction of the ferromagnetic layer 27a is reversed.

The ferromagnetic layer 27a contains iron (Fe). The ferromagnetic layer 27a may further contain at least one element of cobalt (Co) and nickel (Ni). Further, the ferromagnetic layer 27a may further contain boron (B). More specifically, for example, the ferromagnetic layer 27a contains cobalt iron boron (CoFeB) or iron boride (FeB).

The ferromagnetic layer 27a may contain a stacked film of a layer A and a layer B from the viewpoint of increasing a retention energy ΔE of a storage layer for data retention. The layer A is a layer containing at least one element selected from cobalt (Co), iron (Fe), and nickel (Ni). The layer B is a layer containing at least one element selected from platinum (Pt), iridium (Ir), ruthenium (Ru), osmium (Os), palladium (Pd), and gold (Au). Examples of the stacked film include a Co/Pt stacked film, a Co/Ir stacked film, a Co/Pd stacked film, and the like. When (001) oriented magnesium oxide (MgO) is used for the non-magnetic layer 27b, the stacked film is further stacked with a layer C (interface layer) containing cobalt iron boron (CoFeB) or the like. In this case, the stacked film is in contact with the non-magnetic layer 24c and the layer C is in contact with the non-magnetic layer 27b.

The non-magnetic layer 27b is provided on the upper surface of the ferromagnetic layer 27a. The non-magnetic layer 27b is a non-magnetic insulating film. The non-magnetic layer 27b is used as a tunnel barrier layer. The non-magnetic layer 27b is provided between the ferromagnetic layer 27a and the ferromagnetic layer 27c, and forms a magnetic tunnel junction together with these two ferromagnetic layers. Further, when an initial amorphous layer such as cobalt iron boron (CoFeB) is used for the interface layer of the ferromagnetic layer 27a and the ferromagnetic layer 27c, in the crystallization treatment of the ferromagnetic layer 27a, the non-magnetic layer 27b functions as a core seed material for growing the crystalline film from the interface with the ferromagnetic layer 27a. Here, the initial amorphous layer is an amorphous state immediately after film deposition and crystallizes after annealing treatment. The non-magnetic layer 27b has a NaCl-type crystal structure with (001) orientation. Examples of the compound used for the non-magnetic layer 27b include magnesium oxide (MgO). When magnesium oxide (MgO) is used for the non-magnetic layer 27b, the (001) interface of magnesium oxide (MgO) and the (001) interface of cobalt iron boron (CoFeB) grow in alignment with each other. Therefore, cobalt iron boron (CoFeB) has a (100) oriented body-centered cubic (BCC) structure. When (001) oriented magnesium oxide (MgO), magnesium-aluminum oxide (MgAlO), or the like is used, cobalt iron boron (CoFeB) or the like as an interface layer may not be required.

The ferromagnetic layer 27c is provided on the upper surface of the non-magnetic layer 27b. The ferromagnetic layer 27c is a conductive film having ferro-magnetic property. The ferromagnetic layer 27c is used as a reference layer. The ferromagnetic layer 27c has an axial direction for easy magnetization in a direction perpendicular to the film surface (Z direction). The magnetization direction of the ferromagnetic layer 27c is fixed. In the example of FIG. 5, the magnetization direction of the ferromagnetic layer 27c is directed toward the ferromagnetic layer 27a. The phrase “the magnetization direction is fixed” means that the magnetization direction does not change due to a torque having a magnitude that can reverse the magnetization direction of the ferromagnetic layer 27a. The ferromagnetic layer 27c includes, for example, at least one alloy film selected from cobalt platinum (CoPt), cobalt nickel (CoNi), and cobalt palladium (CoPd). A stacked film such as a Co/Pt stacked film or a Co/Pd stacked film may also be used. When the (001) oriented MgO is used for the non-magnetic layer 27b, an initial amorphous layer such as CoFeB or the like as an interface layer is used for the ferromagnetic layer 27c. The initial amorphous layer is used by stacking the CoPt, CoPd, Co/Pt stacked film, Co/Pd stacked film, and the like. In this case, the layer containing CoFeB among the ferromagnetic layers 27c is formed on the non-magnetic layer 27b side with (001) oriented MgO more than the other layers.

The non-magnetic layer 27d is provided on the upper surface of the ferromagnetic layer 27c. The non-magnetic layer 27d is a non-magnetic conductive film. The non-magnetic layer 27d is used as a spacer layer. For example, the non-magnetic layer 27d is composed of elements selected from ruthenium (Ru), osmium (Os), rhodium (Rh), iridium (Ir), vanadium (V), and chromium (Cr), or the alloys thereof. For example, the film thickness of the non-magnetic layer 27d is 2 nm or less.

The ferromagnetic layer 27e is provided on the upper surface of the non-magnetic layer 27d. The ferromagnetic layer 27e is a conductive film having ferro-magnetic property. The ferromagnetic layer 27e is used as a shift cancelling layer. The ferromagnetic layer 27e has an axial direction for easy magnetization in a direction perpendicular to the film surface (Z direction). The ferromagnetic layer 27e contains, for example, at least one alloy layer selected from cobalt platinum (CoPt), cobalt nickel (CoNi), and cobalt palladium (CoPd). The ferromagnetic layer 27e may be a stacked film such as a Co/Pt stacked film and a Co/Pd stacked film.

The ferromagnetic layer 27c and the ferromagnetic layer 27e are anti-ferromagnetically coupled by the non-magnetic layer 27d. That is, the ferromagnetic layer 27c and the ferromagnetic layer 27e are coupled so as to have magnetization directions antiparallel to each other. Such a coupling structure of the ferromagnetic layer 27c, the non-magnetic layer 27d, and the ferromagnetic layer 27e is called a synthetic anti-ferromagnetic (SAF) structure. Due to the SAF structure, the ferromagnetic layer 27e cancels the effect of the leakage magnetic field of the ferromagnetic layer 27c on the magnetization direction change of the ferromagnetic layer 27a, and can reduce the leakage magnetic field of the substantial ferromagnetic layer 27c.

The magnetoresistance effect element MTJ can take either a low resistance state or a high resistance state depending on whether the relative relationship between the magnetization directions of the storage layer and the reference layer is parallel or antiparallel. In the embodiment, the magnetization direction of the storage layer with respect to the magnetization direction of the reference layer is controlled without passing a write current through such a magnetoresistance effect element MTJ. Specifically, a writing method using the spin orbit torque generated by passing a current through the wiring SOTL is adopted.

When a write current Ic0 of a certain magnitude is passed through the wiring SOTL in the Y direction, the relative relationship between the magnetization directions of the storage layer and the reference layer becomes parallel. In this parallel state, the resistance value of the magnetoresistance effect element MTJ is the lowest, and the magnetoresistance effect element MTJ is set to a low resistance state. This low resistance state is called a “P (parallel) state” and is defined as, for example, a state of data “0”.

Further, when a write current Ic1 larger than the write current Ic0 is passed through the wiring SOTL in the direction opposite to the write current Ic0, the relative relationship between the magnetization directions of the storage layer and the reference layer becomes antiparallel. In this antiparallel state, the resistance value of the magnetoresistance effect element MTJ is highest, the magnetoresistance effect element MTJ is set to a high resistance state. This high resistance state is called an “AP (antiparallel) state” and is defined as, for example, a state of data “1”.

The method of defining data “1” and data “0” is not limited to the above-mentioned example. For example, the P state may be defined as data “1” and the AP state may be defined as data “0”.

The shape of the magnetoresistance effect element MTJ seen in the Z direction is elliptical or circular. From the viewpoint of high-density integration of the memory cell MC, the shape of the magnetoresistance effect element MTJ seen in the Z direction is preferably circular. From the viewpoint of reducing the area and power consumption, the short side length when the magnetoresistance effect element MTJ is elliptical and the diameter when the magnetoresistance effect element MTJ is circular are preferably 100 nanometers or less. When performing high-speed magnetization reversal of 5 nsec or less with respect to the ferromagnetic layer 27a, it is preferable that the diameter of the magnetoresistance effect element MTJ is 30 nanometers or less. When the diameter of the magnetoresistance effect element MTJ is 30 nm or less, the magnetization reversal mode approximately becomes the single magnetic domain mode or the magnetization reversal mode in which a clear magnetic wall is not formed. As a result, high-speed magnetization reversal is realized.

### 1.2 Operation

Next, the operation of the magnetic memory device according to the first embodiment will be described.

### 1.2.1 Relationship Between Various Operations and Temperature of Magnetic Layer

FIG. 8 is a view illustrating an example of the relationship between various operations and the temperature of the magnetic layer in the magnetic memory device according to the first embodiment.

The state of the magnetic memory device 1 is divided into, for example, a write state, a read state, and a standby state. The write state is a state in which data is written to the memory cell array 10 (a write operation is being executed). The read state is a state in which data is being read from the memory cell array 10 (a read operation is being executed). The standby state is a state in which neither a write operation nor a read operation is being executed.

In the standby state or the read state, the temperature T of the magnetic layer 24b is designed to be less than the threshold temperature TA. On the other hand, in the write state, the temperature T of the magnetic layer 24b is designed to exceed the threshold temperature TA. Thereby, the magnetic characteristics of the magnetic layer 24b can be changed depending on whether or not a write operation is being executed. Specifically, when a write operation is not being executed, the magnetic layer 24b exhibits antiferro-magnetic property. On the other hand, when a write operation is being executed, the magnetic layer 24b exhibits ferro-magnetic property.

### 1.2.2 Write Operation

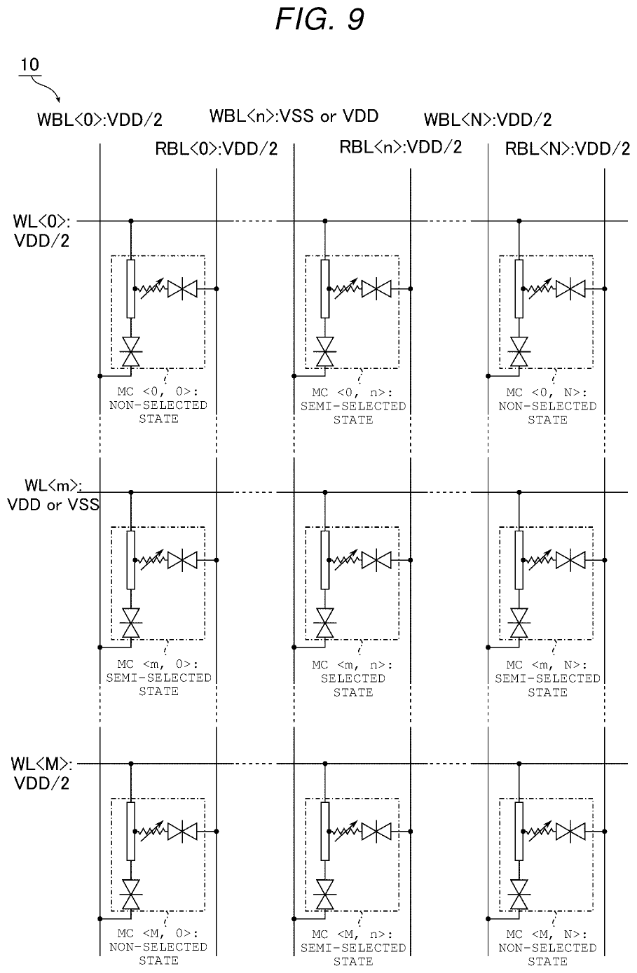

FIG. 9 is a circuit view illustrating an example of a write operation in the magnetic memory device according to the first embodiment. In the example of FIG. 9, a case where data is written into the memory cell MC<m, n> among the plurality of memory cells MC is illustrated (0<m<M, 0<n<N).

When data is written into the memory cell MC<m, n>, a voltage VDD or VSS is applied to each of the word line WL<m> and the write bit line WBL<n>. When the voltage VDD is applied to the word line WL<m>, the voltage VSS is applied to the write bit line WBL<n>. When the voltage VSS is applied to the word line WL<m>, the voltage VDD is applied to the write bit line WBL<n>. A voltage VDD/2 is applied to all the word lines WL other than the word line WL<m>, all the write bit lines WBL other than the write bit line WBL<n>, and all the read bit lines RBL.

The voltage VSS is a reference voltage. The voltage VSS is, for example, 0 V. The voltage VDD (representing the voltage difference between the voltage VDD and the voltage VSS) is a voltage that turns on the switching elements SEL1 and SEL2. Further, the voltage difference of VDD is a voltage at which a current can be passed to change the resistance state of the magnetoresistance effect element MTJ. A voltage difference of VDD/2 is a voltage that turns off the switching elements SEL1 and SEL2.

As a result, the voltage difference of VDD is generated between the word line WL<m> and the write bit line WBL<n>. A voltage difference of VDD/2 is generated between the word line WL<m> and any write bit line WBL other than the write bit line WBL<n>. A voltage difference of VDD/2 is generated between the word line WL<m> and any read bit line RBL.

Further, a voltage difference of VDD/2 is generated between any word line WL other than the word line WL<m> and the write bit line WBL<n>. No voltage difference is generated between any word line WL other than the word line WL<m> and any write bit line WBL other than the write bit line WBL<n>. No voltage difference is generated between any word line WL other than the word line WL<m> and any read bit line RBL.

A voltage difference of VDD/2 is generated between the write bit line WBL<n> and the read bit line RBL<n>. No voltage difference is generated between any write bit line WBL other than the write bit line WBL<n> and the corresponding read bit line RBL.

Therefore, a switching element SEL1<m, n> is turned on. All the switching elements SEL1 other than the switching element SEL1<m, n> are turned off. Further, all the switching elements SEL2 are turned off.

Therefore, it is possible to pass a current through the wiring SOTL<m, n> without passing a current through all the wirings SOTL other than the wiring SOTL<m, n> and all the magnetoresistance effect elements MTJ.

In the above-mentioned write operation, the state of the memory cell MC<m, n> is also called a selected state. The state of the memory cells MC<0, n> to MC<m−1, n>, MC<m+1, n> to MC<M, n>, MC<m, 0> to MC<m, n−1>, and MC<m, n+1> to MC<m, N> is also called a semi-selected state. The state of all the memory cells MC that are not in a selected state or a semi-selected state is also called a non-selected state.

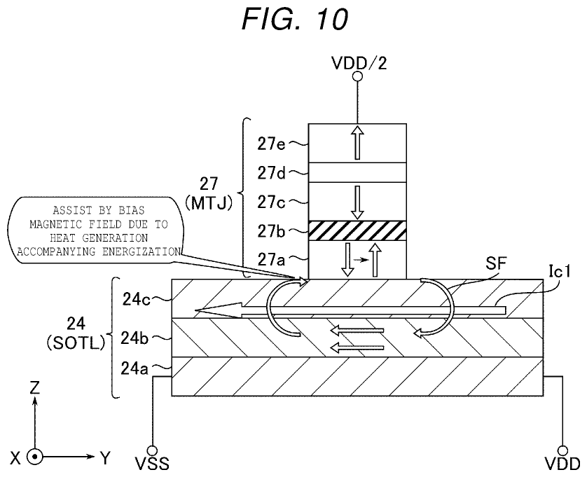

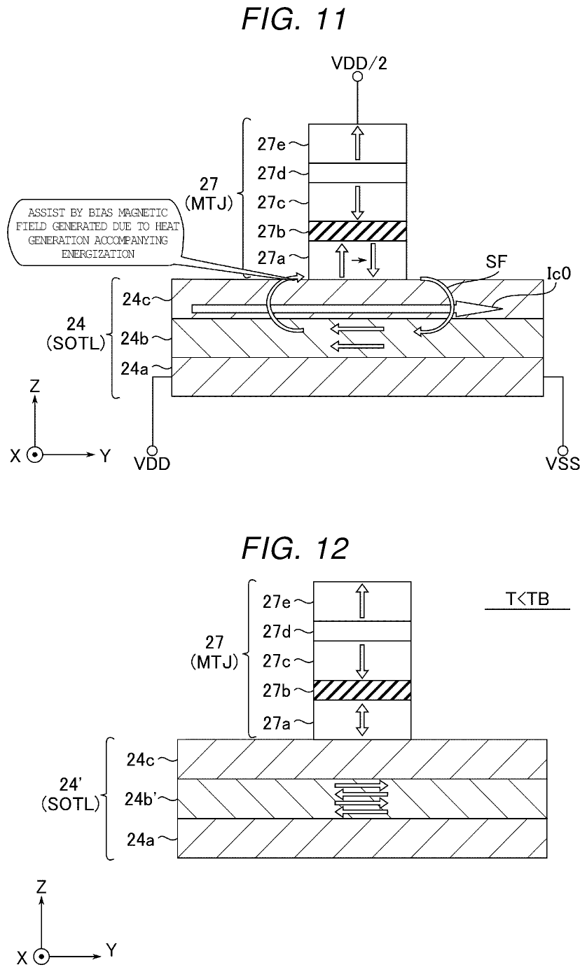

FIGS. 10 and 11 are cross-sectional views illustrating an example of a write operation in the magnetic memory device according to the first embodiment. FIGS. 10 and 11 schematically illustrate the current flowing through the selected memory cell MC and the magnetization direction of the magnetoresistance effect element MTJ. FIG. 10 corresponds to a write operation when writing data “1”. FIG. 11 corresponds to a write operation when writing data “0”.

First, the operation of writing data “1” will be described with reference to FIG. 10. In the example of FIG. 10, a case where the write current Ic1 flows from the word line WL (right side of the paper surface) to the write bit line WBL (left side of the paper surface) is illustrated.

As described above, a voltage difference of VDD that turns on the switching element SEL1 is generated at both ends of the conductor layer 24. By controlling the voltage difference of VDD, the write current Ic1 flows in the conductor layer 24. When the write current Ic1 flows in the conductor layer 24, particularly in the non-magnetic layer 24c, a spin orbit torque is generated that attempts to make the magnetization direction of the ferromagnetic layer 27a antiparallel to the magnetization direction of the ferromagnetic layer 27c. The spin orbit torque acts on the ferromagnetic layer 27a close to the non-magnetic layer 24c.

Further, the temperature T of the magnetic layer 24b exceeds the threshold temperature TA due to the write current Ic1 flowing in the conductor layer 24. As a result, the magnetic layer 24b undergoes a phase change from antiferro-magnet to ferro-magnet. Therefore, the magnetic layer 24b generates magnetization and also generates the leakage magnetic field SF outside the magnetic layer 24b. The magnetization direction of the magnetic layer 24b does not depend on a direction in which the write current Ic1 flows. In the example of FIG. 10, the leakage magnetic field SF is applied to the ferromagnetic layer 27a in the +Y direction antiparallel to the magnetization direction inside the magnetic layer 24b.

As a result, the magnetization direction of the ferromagnetic layer 27a is reversed in a direction antiparallel to the magnetization direction of the ferromagnetic layer 27c by a spin orbit torque and assist by the leakage magnetic field SF. By operating as described above, a write operation of data “1” is completed.

Next, the operation of writing data “0” will be described with reference to FIG. 11. In the example of FIG. 11, a case where the write current Ic0 flows from the write bit line WBL (left side of the paper surface) to the word line WL (right side of the paper surface) is illustrated.

As described above, a voltage difference of VDD that turns on the switching element SEL1 is generated at both ends of the conductor layer 24. By controlling the voltage difference of VDD, the write current Ic0 flows in the conductor layer 24. When the write current Ic0 flows in the conductor layer 24, particularly in the non-magnetic layer 24c, a spin orbit torque is generated that attempts to make the magnetization direction of the ferromagnetic layer 27a parallel to the magnetization direction of the ferromagnetic layer 27c. The spin orbit torque acts on the ferromagnetic layer 27a close to the non-magnetic layer 24c.

Further, the temperature T of the magnetic layer 24b exceeds the threshold temperature TA due to the write current Ic0 flowing in the conductor layer 24. As a result, the magnetic layer 24b undergoes a phase change from antiferro-magnet to ferro-magnet. Therefore, the magnetic layer 24b generates magnetization and also generates the leakage magnetic field SF outside the magnetic layer 24b. The magnetization direction of the magnetic layer 24b does not depend on a direction in which the write current Ic0 flows. In the example illustrated in FIG. 11, similar to FIG. 10, the leakage magnetic field SF is applied to the ferromagnetic layer 27a in the +Y direction antiparallel to the magnetization direction inside the magnetic layer 24b.

As a result, the magnetization direction of the ferromagnetic layer 27a is reversed in a direction parallel to the magnetization direction of the ferromagnetic layer 27c by spin orbit torque and assist by the leakage magnetic field SF. By operating as described above, a write operation of data “0” is completed.

### 1.3 Effects Related to First Embodiment

In the first embodiment, in an MRAM having the magnetoresistance effect element MTJ having vertical magnetization, a writing method utilizing a spin orbit torque is applied. In this case, a bias magnetic field is required to act on the magnetoresistance effect element MTJ. A configuration for generating a bias magnetic field may be a cause of complicated device structure. According to the first embodiment, the load of a write operation can be reduced by generating a bias magnetic field while avoiding the complication of the device structure. Hereinafter, this effect according to the first embodiment will be described.

The wiring SOTL includes a first portion coupled to the word line WL, a second portion coupled to the write bit line WBL, and a third portion coupled to the read bit line RBL. The magnetoresistance effect element MTJ is coupled between the third portion of the wiring SOTL and the read bit line RBL. The switching element SEL1 is coupled between the second portion of the wiring SOTL and the write bit line WBL. The switching element SEL2 is coupled between the magnetoresistance effect element MTJ and the read bit line RBL. This makes it possible to configure the memory cell MC to which the writing method using the spin orbit torque is applied.

The wiring SOTL includes the magnetic layer 24b. The magnetic layer 24b has an alloy containing iron (Fe) and rhodium (Rh). As a result, the magnetic layer 24b can have a magnetic characteristic of exhibiting antiferro-magnetic property when the temperature is lower than the threshold temperature TA and exhibiting ferro-magnetic property when the temperature exceeds the threshold temperature TA.

The magnetic layer 24b further contains at least one element selected from iridium (Ir), ruthenium (Ru), palladium (Pd), osmium (Os), platinum (Pt), gold (Au), silver (Ag), and copper (Cu) as additives, thereby adjusting the threshold temperature TA of the magnetic layer 24b to a temperature of a desired level.

Specifically, the temperature T of the magnetic layer 24b is designed to exceed the threshold temperature TA due to heat generated by each of the currents Ic0 and Ic1 flowing through the magnetic layer 24b in the write state. As a result, the leakage magnetic field SF can be generated as a bias magnetic field in the write state. Therefore, the magnetic layer 24b can assist the reversal of the magnetization direction of the ferromagnetic layer 27a due to the spin-orbit torque.

On the other hand, the temperature T of the magnetic layer 24b is designed to be less than the threshold temperature TA in the standby state or the read state. Thereby, in the standby state or the read state, it is possible to prevent the leakage magnetic field SF as a bias magnetic field from being generated. Therefore, the magnetic layer 24b can prevent the application of an unnecessary external magnetic field to the magnetoresistance effect element MTJ. Therefore, by avoiding the application of an unnecessary bias magnetic field, deterioration of the retention characteristics of the storage layer of the magnetoresistance effect element MTJ during standby can be prevented.

### 2. Second Embodiment

Next, a second embodiment will be described. In the second embodiment, the mechanism of generating magnetization in the wiring SOTL is different from that in the first embodiment. The following description mainly describes the configuration and operation different from the first embodiment. As for the configuration and operation equivalent to the first embodiment, the description is appropriately omitted.

### 2.1 Configuration of Magnetoresistance Effect Element and Peripheral Wiring

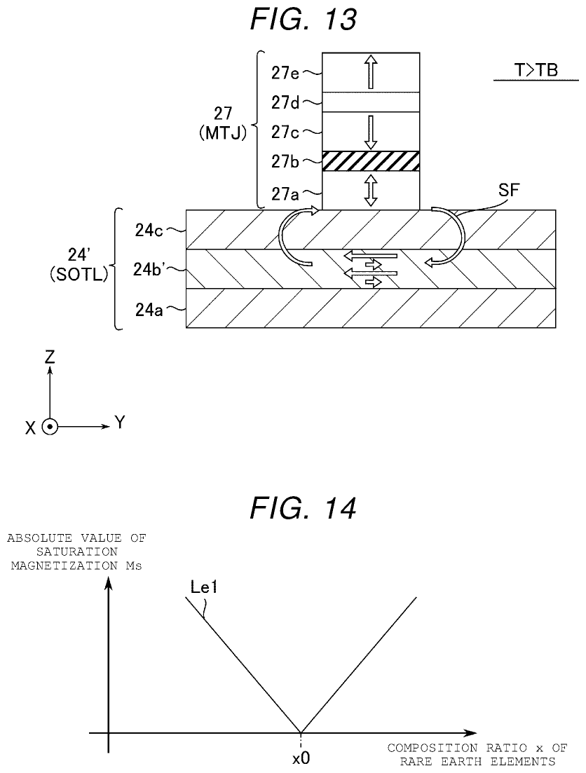

FIGS. 12 and 13 are cross-sectional views illustrating an example of the cross-sectional structure of a magnetoresistance effect element and a peripheral wiring according to the second embodiment. FIGS. 12 and 13 correspond to FIGS. 5 and 6 in the first embodiment, respectively. Specifically, FIG. 12 corresponds to the case where the wiring SOTL is at a low temperature. FIG. 13 corresponds to the case where the wiring SOTL is at a high temperature.

In the second embodiment, a conductor layer 24′ is provided as the wiring SOTL instead of the conductor layer 24. That is, the conductor layer 24′ includes the non-magnetic layer 24a, a magnetic layer 24b′, and the non-magnetic layer 24c. The configurations of the non-magnetic layer 24a and the non-magnetic layer 24c are the same as the configurations of the non-magnetic layer 24a and the non-magnetic layer 24c in the first embodiment. The configuration of the element layer 27 is the same as the configuration of the element layer 27 in the first embodiment.

The magnetic layer 24b′ is provided between the non-magnetic layer 24a and the non-magnetic layer 24c. The magnetic layer 24b′ is a conductive film including ferri-magnetic alloys. The magnetic layer 24b′ contains at least one magnetic element (3d transition metal ferromagnetic element) selected from iron (Fe), cobalt (Co), and nickel (Ni). The magnetic layer 24b′ contains at least one rare earth element selected from lanthanum (La), cesium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), yttrium (Yb), and lutetium (Lu). The magnetic layer 24b′ may be a single layer film of an alloy containing a magnetic element and a rare earth element.

When the magnetic layer 24b′ is a single layer film, the magnetic layer 24b′ has an amorphous structure. The magnetic layer 24b′ may be a stacked film in which a layer containing a magnetic element and a layer containing a rare earth element are stacked in this order. When the magnetic layer 24b′ is a stacked film, the layer containing at least a rare earth element among the magnetic layer 24b′ has an amorphous structure. As described above, by having the amorphous structure, the magnetic layer 24b′ is designed to have a high resistance. From the viewpoint of preventing current shunting, the magnetic layer 24b′ preferably has a thin film with a high resistance. The film thickness of the magnetic layer 24b′ is preferably 2 nanometers or more and 10 nanometers or less.

The magnetic characteristics of the magnetic layer 24b′ change with a threshold temperature TB as a boundary. That is, the threshold temperature TB is the compensation temperature of the magnetic layer 24b′. Specifically, as illustrated in FIG. 12, when the temperature T of the magnetic layer 24b′ is less than the threshold temperature TB (T<TB), the net saturation magnetization Ms of the magnetic layer 24b′ becomes almost zero. As a result, the magnetic layer 24b′ does not generate the leakage magnetic field SF outside the magnetic layer 24b. Therefore, the leakage magnetic field SF is not applied to the ferromagnetic layer 27a.

On the other hand, as illustrated in FIG. 13, when the temperature T of the magnetic layer 24b′ exceeds the threshold temperature TB (T>TB), the net saturation magnetization Ms of the magnetic layer 24b′ is significantly larger than zero. The magnetization direction of the magnetic layer 24b′ is stabilized along the Y direction due to, for example, shape anisotropy. The magnetization direction of the magnetic layer 24b′ is reversed according to the direction of a current flowing in the magnetic layer 24b′. That is, the magnetic layer 24b′ has an axial direction for easy magnetization in the extending direction (Y direction) of the magnetic layer 24b′. The magnetic layer 24b′ generates the leakage magnetic field SF outside the magnetic layer 24b′. Therefore, the leakage magnetic field SF is applied to the ferromagnetic layer 27a.

The direction of the leakage magnetic field SF applied to the ferromagnetic layer 27a is antiparallel to the magnetization direction of the magnetic layer 24b′. The spin orbit torque generated in the non-magnetic layer 24c acts on the ferromagnetic layer 27a. When the leakage magnetic field SF of a predetermined magnitude is applied and a spin-orbit torque of a predetermined magnitude acts, as in the first embodiment, the magnetization direction of the ferromagnetic layer 27a is configured to be reversed.

The magnetic characteristics of the magnetic layer 24b′ as described above are achieved by adjusting the composition of the magnetic layer 24b′.

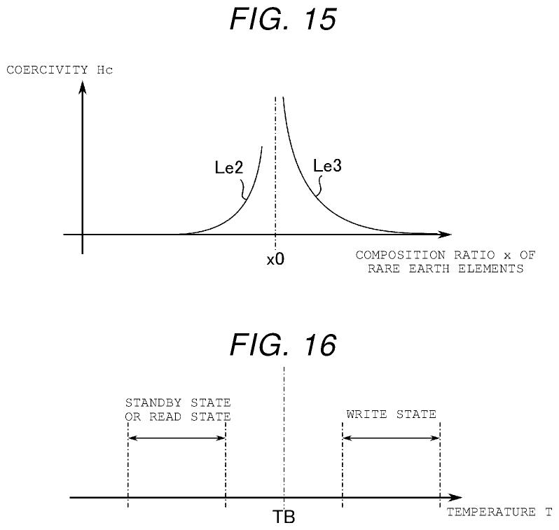

FIG. 14 is a view illustrating an example of the relationship between the composition of the magnetic layer and the saturation magnetization according to the second embodiment. FIG. 15 is a view illustrating an example of the relationship between the composition and coercivity of the magnetic layer according to the second embodiment. In FIGS. 14 and 15, when the composition of the magnetic element TM and the rare earth element RE contained in the magnetic layer 24b′ is expressed by REₓTM₍₁₀₀₋ₓ₎, the composition ratio x of the rare earth element is illustrated on the horizontal axis. In FIG. 14, the change in the net saturation magnetization Ms with respect to a composition ratio x is illustrated by a line Le1. In FIG. 15, the change in the coercivity (Hc) with respect to the composition ratio x is illustrated by lines Le2 and Le3.

As illustrated by the line Le1, as the composition ratio x of the rare earth element approaches x0, the net saturation magnetization Ms becomes smaller. When the composition ratio x is x0, the net saturation magnetization Ms becomes zero.

As illustrated by the lines Le2 and Le3, the coercivity Hc increases as the composition ratio x of the rare earth element approaches x0. When the composition ratio x is x0, the coercivity Hc diverges.

The composition of the magnetic layer 24b′ having such a composition ratio x0 is also referred to as a compensating composition. The composition ratio x0 such that the magnetic layer 24b′ becomes a compensating composition can be realized, for example, in the range of 20 at % or more and 30 at % or less. Conceptually, the compensating composition is better. However, from the viewpoint of controllability, the composition may be set so that the composition of ferromagnetic elements is slightly greater than the compensating composition.

### 2.2 Relationship between Various Operations and Temperature of Magnetic Layer

FIG. 16 is a view illustrating an example of the relationship between various operations and the temperature of the magnetic layer in the magnetic memory device according to the second embodiment. FIG. 16 corresponds to FIG. 8 in the first embodiment.

In the standby state or the read state, the temperature T of the magnetic layer 24b′ is designed to be less than the threshold temperature TB. On the other hand, in the write state, the temperature T of the magnetic layer 24b′ is designed to exceed the threshold temperature TB. As a result, the magnetic layer 24b′ can change the net saturation magnetization Ms depending on whether or not the write operation is executed. Specifically, when a write operation is not being executed, the net saturation magnetization Ms of the magnetic layer 24b′ is almost zero. On the other hand, when the write operation is being executed, the net saturation magnetization Ms of the magnetic layer 24b′ is significantly larger than zero.

### 2.3 Write Operation

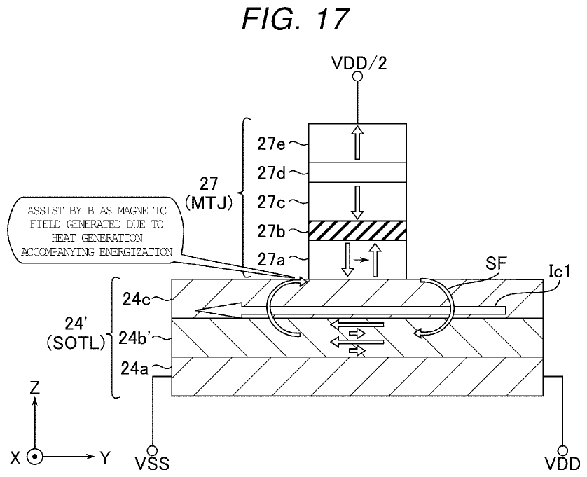

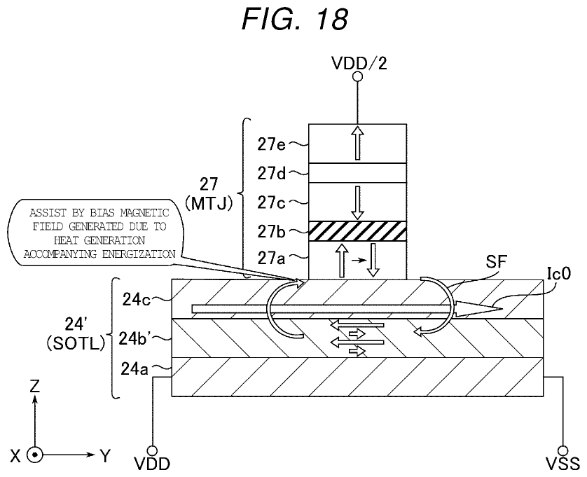

FIGS. 17 and 18 are cross-sectional views illustrating an example of a write operation in the magnetic memory device according to the second embodiment. FIGS. 17 and 18 correspond to FIGS. 10 and 11, respectively, in the first embodiment. Specifically, FIG. 17 corresponds to a write operation when writing data “1”. FIG. 18 corresponds to a write operation when writing data “0”.

First, the operation of writing data “1” will be described with reference to FIG. 17. In the example of FIG. 17, a case where the write current Ic1 flows from the word line WL (right side of the paper surface) to the write bit line WBL (left side of the paper surface) is illustrated.

As described above, a voltage difference of VDD that turns on the switching element SEL1 is generated at both ends of the conductor layer 24′. By controlling the voltage difference of VDD, the write current Ic1 flows in the conductor layer 24′. When the write current Ic1 flows in the conductor layer 24′, particularly in the non-magnetic layer 24c, a spin orbit torque is generated that attempts to make the magnetization direction of the ferromagnetic layer 27a antiparallel to the magnetization direction of the ferromagnetic layer 27c. The spin orbit torque acts on the ferromagnetic layer 27a close to the non-magnetic layer 24c.

Further, the temperature T of the magnetic layer 24b′ exceeds the threshold temperature TB due to the write current Ic1 flowing in the conductor layer 24′. As a result, the net saturation magnetization Ms of the magnetic layer 24b′ is significantly larger than zero. Therefore, the magnetic layer 24b′ generates the leakage magnetic field SF outside the magnetic layer 24b′. The magnetization direction of the magnetic layer 24b′ does not depend on a direction in which the write current Ic1 flows. In the example of FIG. 17, the leakage magnetic field SF is applied to the ferromagnetic layer 27a in the +Y direction antiparallel to the magnetization direction inside the magnetic layer 24b′.

As a result, the magnetization direction of the ferromagnetic layer 27a is reversed in a direction antiparallel to the magnetization direction of the ferromagnetic layer 27c by a spin orbit torque and assist by the leakage magnetic field SF. By operating as described above, a write operation of data “1” is completed.

Next, the operation of writing data “0” will be described with reference to FIG. 18. In the example of FIG. 18, a case where the write current Ic0 flows from the write bit line WBL (left side of the paper surface) to the word line WL (right side of the paper surface) is illustrated.

As described above, a voltage difference of VDD that turns on the switching element SEL1 is generated at both ends of the conductor layer 24. By controlling the voltage difference of VDD, the write current Ic0 flows in the conductor layer 24′. When the write current Ic0 flows in the conductor layer 24′, particularly in the non-magnetic layer 24c, a spin orbit torque is generated that attempts to make the magnetization direction of the ferromagnetic layer 27a parallel to the magnetization direction of the ferromagnetic layer 27c. The spin orbit torque acts on the ferromagnetic layer 27a close to the non-magnetic layer 24c.

Further, the temperature T of the magnetic layer 24b′ exceeds the threshold temperature TB due to the write current Ic0 flowing in the conductor layer 24′. As a result, the net saturation magnetization Ms of the magnetic layer 24b′ is significantly larger than zero. Therefore, the net saturation magnetization Ms of the magnetic layer 24b′ generates the leakage magnetic field SF outside the magnetic layer 24b′. The magnetization direction of the magnetic layer 24b′ does not depend on a direction in which the write current Ic0 flows. In the example illustrated in FIG. 18, similar to FIG. 17, the leakage magnetic field SF is applied to the ferromagnetic layer 27a in the +Y direction antiparallel to the magnetization direction inside the magnetic layer 24b′.

As a result, the magnetization direction of the ferromagnetic layer 27a is reversed in a direction parallel to the magnetization direction of the ferromagnetic layer 27c by spin orbit torque and assist by the leakage magnetic field SF. By operating as described above, a write operation of data “0” is completed.

### 2.4 Effects of Second Embodiment

According to the second embodiment, the wiring SOTL includes the magnetic layer 24b′. The magnetic layer 24b′ contains at least one magnetic element (3d transition metal ferromagnetic element) selected from iron (Fe), cobalt (Co), and nickel (Ni), and at least one rare earth element selected from lanthanum (La), cesium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), yttrium (Yb), and lutetium (Lu). As a result, the magnetic layer 24b′ functions as a ferrimagnetic material having the threshold temperature TB as a compensation temperature.

Here, the ferri-magnetic material is a material composed at least of one rare earth element and one ferromagnetic element, which are magnetically coupled so that the directions of the magnetization thereof are opposite from each other. Specifically, when the net saturation magnetization Ms of the magnetic layer 24b′ is less than the threshold temperature TB, the saturation magnetization Ms can be set to the minimum (almost zero) by controlling the composition. When the net saturation magnetization Ms of the magnetic layer 24b′ exceeds the threshold temperature TB, as the saturation magnetization Ms on the rare earth element side disappears by the temperature characteristics, the saturation magnetization Ms on the ferromagnetic element side appears. As a result, the net saturation magnetization Ms of the magnetic layer 24b′ has a characteristic of becoming significantly larger than an initial state when the temperature exceeds the threshold temperature TB. A magnetic material having such characteristics is also called a rare earth ferri-magnetic material. The rare earth ferri-magnetic material has a compensating composition in which the net saturation magnetization Ms becomes zero at room temperature and the composition ratio of the rare earth element is 20 at % or more and 30 at % or less. The composition of such a rare earth ferri-magnetic material is described as REₓTM_{100-X} (20≤×30 at %). Here, TM is a 3d ferromagnetic element such as Co, Fe, and Ni. RE is a rare earth element. Practically, it is preferable that the composition of the rare earth ferri-magnetic material in the initial state is selected so that the composition of TM is slightly greater than the compensating composition and the net saturation magnetization Ms is slightly zero or more.

The temperature T of the magnetic layer 24b′ is designed to exceed the threshold temperature TB due to heat generation or current disturbance accompanying the current Ic0 or Ic1 flowing through the magnetic layer 24b′ in the write state. As a result, the leakage magnetic field SF can be generated as a bias magnetic field in the write state. Therefore, the magnetic layer 24b′ can assist the reversal of the magnetization direction of the ferromagnetic layer 27a due to the spin-orbit torque.

On the other hand, the temperature T of the magnetic layer 24b′ is designed to be less than the threshold temperature TB in the standby state or the read state. Thereby, in the standby state or the read state, it is possible to prevent the leakage magnetic field SF as a bias magnetic field from being generated. Therefore, the magnetic layer 24b′ can prevent the application of an unnecessary external magnetic field to the magnetoresistance effect element MTJ. Therefore, as in the first embodiment, by avoiding the application of an unnecessary bias magnetic field, deterioration of the retention characteristics of the storage layer of the magnetoresistance effect element MTJ during standby can be prevented.

### 3. Modification Examples

The first and second embodiments described above are not limited to the above examples, and various modification examples are applicable.

In the first and second embodiments described above, a case where the leakage magnetic field SF generated from the magnetic layers 24b and 24b′ is applied to the ferromagnetic layer 27a as a bias magnetic field has been described. However, the bias magnetic field applied to the ferromagnetic layer 27a is not limited to the leakage magnetic field SF. For example, a bias magnetic field may be generated by utilizing the exchange coupling between the magnetic layers 24b and 24b′ and the ferromagnetic layer 27a. In this case, a bias magnetic field is generated at the interface between the ferromagnetic layer 27a and the non-magnetic layer 24c. A bias magnetic field utilizing an exchange coupling acts on the magnetoresistance effect element MTJ only when spontaneous magnetization occurs in the magnetic layer 24b or the magnetic layer 24b′ due to heat generation accompanying energization, similar to a bias magnetic field utilizing the leakage magnetic field SF. Therefore, when the magnetic layer 24b does not generate heat to the extent that the magnetic layer 24b exceeds the threshold temperature TA or the magnetic layer 24b′ exceeds the threshold temperature TB as in the standby state or the read state, application of an unnecessary external magnetic field to the magnetoresistance effect element MTJ can be prevented.

In the first and second embodiments described above, a case where a selector is applied as a two-terminal type switching element applied to the switching element SEL2 is described, but not limited thereto. For example, a diode may be applied to the switching element SEL2.

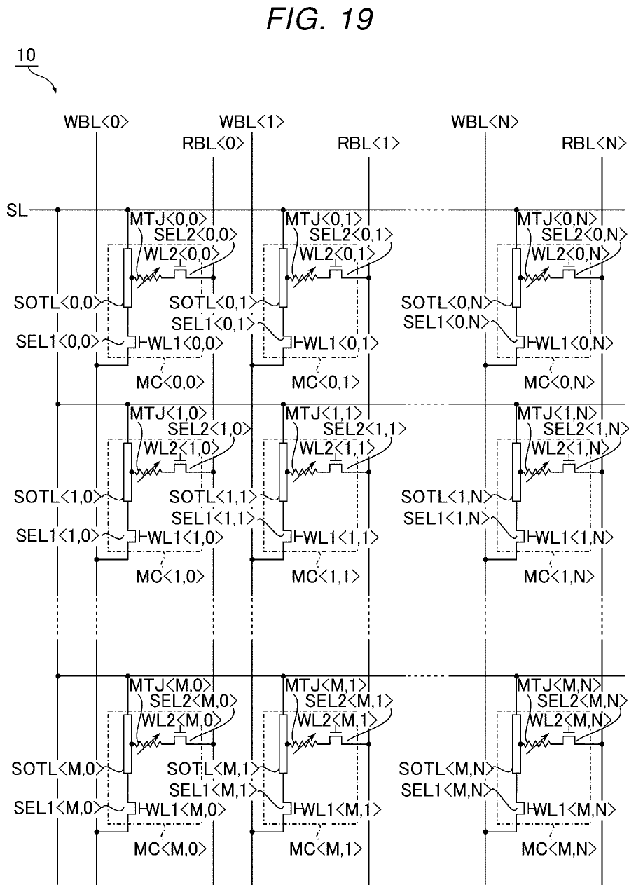

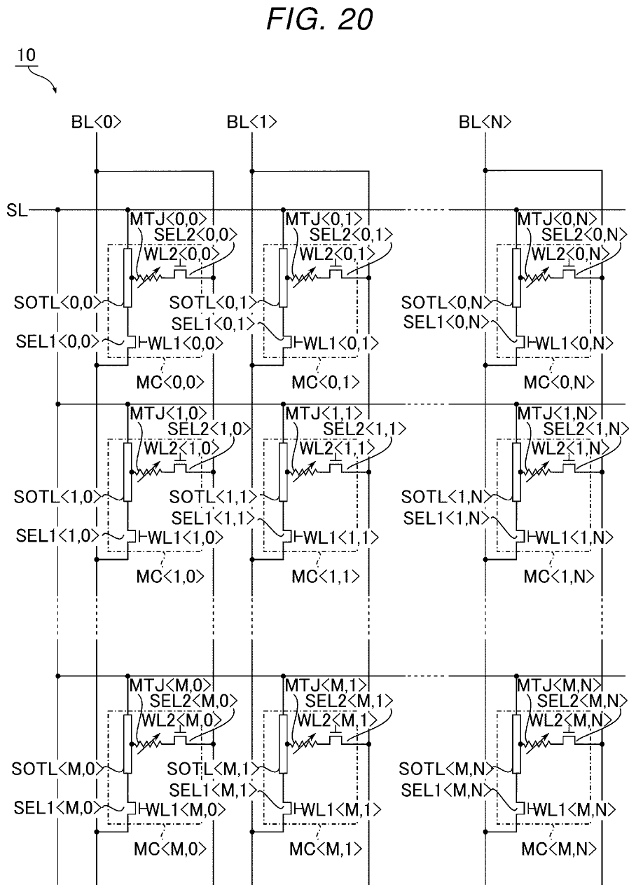

In the first and second embodiments described above, a case where a two-terminal type switching element is applied to the switching elements SEL1 and SEL2 is described, but not limited thereto. For example, as illustrated in FIGS. 19 and 20, a three-terminal type switching element may be applied to the switching elements SEL1 and SEL2. Specifically, for example, a transistor such as surrounding gate transistor (SGT) may be applied to the switching elements SEL1 and SEL2. In this case, the first portions of all wirings SOTL are commonly connected to a source line SL. The source line SL is, for example, grounded. The gate of the switching element SEL1<i, j> is coupled to the word line WL1<i, j>. The gate of the switching element SEL2<i, j> is coupled to the word line WL2<i, j>. In this way, one memory cell MC can be selected when each switching element SEL1 and SEL2 is controlled by individual word lines WL1 and WL2, respectively.

As illustrated in FIG. 19, when a three-terminal type switching element is applied to the switching elements SEL1 and SEL2, the switching elements SEL1 and SEL2 in the same memory cell MC may be coupled to the corresponding write bit line WBL and the read bit line RBL, respectively. As illustrated in FIG. 20, when a three-terminal type switching element is applied to the switching elements SEL1 and SEL2, the switching elements SEL1 and SEL2 in the same memory cell MC are commonly coupled to the corresponding bit line BL.

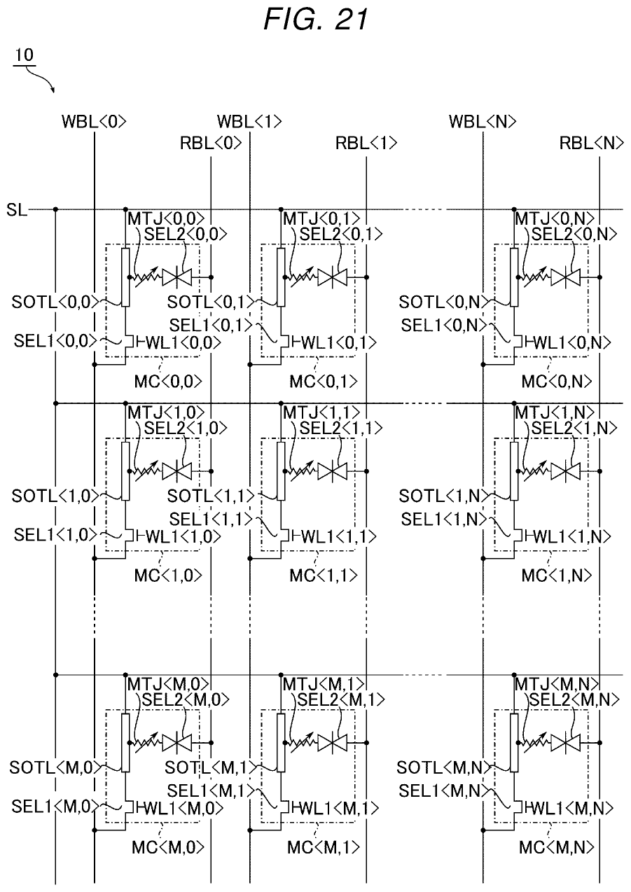

In the first and second embodiments described above, a case in which the switching elements SEL1 and SEL2 are both a two-terminal type or a three-terminal type is described, but not limited thereto. For example, as illustrated in FIG. 21, the switching elements SEL1 and SEL2 may have a three-terminal type and a two-terminal type switching element, respectively. In this case, the first portions of all wirings SOTL are commonly connected to a source line SL. The source line SL is, for example, grounded. The gate of the switching element SEL1<i, j> is coupled to the word line WL1<i, j>. The switching elements SEL1 and SEL2 in the same memory cell MC are coupled to the corresponding write bit line WBL and read bit line RBL, respectively. As a result, one memory cell MC can be selected.

In the first and second embodiments described above, a case where two hierarchical structures L1 and L2 are stacked above the semiconductor substrate 20 is described, but not limited thereto. For example, three or more hierarchical structures having the same structure may be stacked on the semiconductor substrate 20. Further, for example, one hierarchical structure may be stacked above the semiconductor substrate 20.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A magnetic memory device comprising:
a first conductor layer;
a second conductor layer;
a third conductor layer; and
a three-terminal type memory cell that is coupled to the first conductor layer, the second conductor layer, and the third conductor layer, wherein
the memory cell includes:
a fourth conductor layer that includes a first portion coupled to the first conductor layer, a second portion coupled to the second conductor layer, and a third portion coupled to the third conductor layer and located between the first portion and the second portion, and
a magnetoresistance effect element that is coupled between the third conductor layer and the fourth conductor layer;
the fourth conductor layer includes a magnetic layer and a first non-magnetic layer that is provided between the magnetic layer and the magnetoresistance effect element; and
the magnetic layer has a first saturation magnetization during a standby state or a read state of the memory cell, and has a second saturation magnetization larger than the first saturation magnetization during a write state of the memory cell.

2. The magnetic memory device according to claim 1, wherein
the magnetic layer exhibits antiferro-magnetic property during the standby state or the read state of the memory cell, and exhibits ferro-magnetic property during the write state of the memory cell.

3. The magnetic memory device according to claim 2, wherein
a temperature of the magnetic layer is less than a phase change temperature of the magnetic layer during the standby state or the read state of the memory cell, and exceeds the phase change temperature during the write state of the memory cell.

4. The magnetic memory device according to claim 2, wherein
the magnetic layer includes an alloy containing iron (Fe) and rhodium (Rh), and
a composition of iron (Fe) in the alloy is 40 at % or more and 60 at % or less.

5. The magnetic memory device according to claim 4, wherein
the magnetic layer further contains at least one element selected from iridium (Ir), palladium (Pd), ruthenium (Ru), osmium (Os), platinum (Pt), gold (Au), silver (Ag), and copper (Cu).

6. The magnetic memory device according to claim 1, wherein
the magnetic layer exhibits ferrimagnetism.

7. The magnetic memory device according to claim 6, wherein
a temperature of the magnetic layer is less than a predetermined temperature during the standby state or the read state of the memory cell, and exceeds the predetermined temperature during the write state of the memory cell.

8. The magnetic memory device according to claim 6, wherein
the magnetic layer contains at least one first element selected from lanthanum (La), cesium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), yttrium (Yb), and lutetium (Lu), and at least one second element selected from iron (Fe), cobalt (Co), and nickel (Ni).

9. The magnetic memory device according to claim 8, wherein
the magnetic layer includes a first layer containing the first element and a second layer containing the second element.

10. The magnetic memory device according to claim 8, wherein
the magnetic layer includes an amorphous alloy containing the first element and the second element.

11. The magnetic memory device according to claim 1, wherein
the first non-magnetic layer contains at least one element selected from tantalum (Ta), tungsten (W), ruthenium (Ru), rhodium (Rh), palladium (Pd), silver (Ag), copper (Cu), osmium (Os), iridium (Ir), platinum (Pt), and gold (Au).

12. The magnetic memory device according to claim 1, wherein
a film thickness of the first non-magnetic layer is 0.3 nanometers or more and 10 nanometers or less.

13. The magnetic memory device according to claim 1, wherein
a film thickness of the magnetic layer is 2 nanometers or more and 10 nanometers or less.

14. The magnetic memory device according to claim 1, wherein
the fourth conductor layer further includes a second non-magnetic layer that is provided on an opposite side of the first non-magnetic layer with respect to the magnetic layer.

15. The magnetic memory device according to claim 14, wherein
the second non-magnetic layer contains at least one element selected from tantalum (Ta), titanium (Ti), and tungsten (W).

16. The magnetic memory device according to claim 14, wherein
a film thickness of the second non-magnetic layer is 0.5 nanometers or more and 5 nanometers or less.

17. The magnetic memory device according to claim 1, wherein
during the write state of the memory cell, the magnetoresistance effect element has
a first resistance value according to a first current flowing from the first portion to the second portion of the fourth conductor layer, and
a second resistance value different from the first resistance value according to a second current flowing from the second portion to the first portion of the fourth conductor layer.

18. The magnetic memory device according to claim 17, wherein
the magnetoresistance effect element includes
a first ferromagnetic layer,
a second ferromagnetic layer that is provided on an opposite side of the fourth conductor layer with respect to the first ferromagnetic layer, and
a third non-magnetic layer that is provided between the first ferromagnetic layer and the second ferromagnetic layer, and
magnetization directions of the first ferromagnetic layer and the second ferromagnetic layer are along a stacking direction of the first ferromagnetic layer, the third non-magnetic layer, and the second ferromagnetic layer.

19. The magnetic memory device according to claim 1, wherein
the memory cell further includes
a first switching element that is coupled between the second conductor layer and the fourth conductor layer, and
a second switching element that is coupled between the first conductor layer and the third conductor layer.

20. The magnetic memory device according to claim 19, wherein
the first switching element is a three-terminal type switching element, and
the second switching element is a two-terminal type switching element.
